(19) United States
(12) Patent Application Publication
(10) Pub. No.: US 2024/0105886 A1
(43) Pub. Date: Mar. 28, 2024

(54) DISPLAY APPARATUS

(71) Applicant: SAMSUNG ELECTRONICS CO., LTD., Suwon-si (KR)

(72) Inventors: Jeongshan NA, Suwon-si (KR); Youngchol LEE, Suwon-si (KR); Naewon JANG, Suwon-si (KR); Dukjin JEON, Suwon-si (KR)

(73) Assignee: SAMSUNG ELECTRONICS CO., LTD., Suwon-si (KR)

(21) Appl. No.: 18/525,286

(22) Filed: Nov. 30, 2023

Related U.S. Application Data
(63) Continuation of application No. PCT/KR2022/008532, filed on Jun. 16, 2022.

(30) Foreign Application Priority Data
Jul. 14, 2021 (KR) 10-2021-0092413

(51) Int. Cl. H01L 33/50; H01L 27/15

(52) U.S. Cl. CPC H01L 33/505; H01L 27/156; H01L 33/507

(57) ABSTRACT

A display apparatus comprises: a light source device configured to emit light; a display panel configured to display the light emitted from the light source device; and an optical sheet disposed at a rear of the display panel, wherein the light source device may include: a substrate; at least one light source electrically connected to the substrate; a light conversion member configured to convert a wavelength of light emitted from the light source; and a conversion member cover covering the light conversion member and configured to allow light to pass therethrough.

### CROSS-REFERENCE TO RELATED APPLICATIONS

This application is continuation application of International Application No. PCT/KR2022/008532, filed on Jun. 16, 2022, which is based on and claims priority to Korean Patent Application No. 10-2021-0092413, filed on Jul. 14, 2021, in the Korean Intellectual Property Office, the disclosures of which are incorporated by reference herein in their entireties.

### BACKGROUND

### 1. Field

The disclosure relates to a display apparatus, and more particularly to a display apparatus with an improved optical structure.

### 2. Description of Related Art

A display apparatus is a type of output device that visually displays data information, such as characters or figures, and images, and includes televisions, various monitors, and various portable terminals (for example, laptop computers, tablet personal computers (PCs), and smartphones).

Display apparatus may be classified into a light-emitting type display apparatus, which uses a display panel that can by itself emit light, such as an organic light-emitting diode (OLED), and a light-receiving type display apparatus using a display panel that cannot by itself emit light and needs to receive light from a backlight unit, such as a liquid crystal display (LCD).

The backlight unit may be classified into a direct type backlight unit in which light sources are positioned at a rear side of the display panel, and an edge type backlight unit in which light sources are positioned on a lateral side of the display panel according to the positions of the light sources.

The display apparatus may include various optical sheets to improve light characteristics of light emitted from light sources. The optical sheet may include a sheet for improving color gamut.

### SUMMARY

Provided is a display apparatus that may be capable of simplifying manufacturing fixation.

Further, provided is a display apparatus that may be capable of reducing manufacturing costs.

Further still, provided is a display apparatus that may be capable of achieving a reduced thickness.

Additional aspects will be set forth in part in the description which follows and, in part, will be apparent from the description, or may be learned by practice of the presented embodiments.

According to an aspect of the disclosure, a display apparatus includes: a light source device configured to emit light; a display panel configured to display the light emitted from the light source device; and an optical sheet disposed at a rear of the display panel, wherein the light source device may include: a substrate; at least one light source electrically connected to the substrate; a light conversion member configured to convert a wavelength of light emitted from the light source; and a conversion member cover covering the light conversion member and configured to allow light to pass therethrough.

The at least one light source may include a first light source on a first side of the light conversion member and a second light source on a second side of the light conversion member opposite to the first side.

The conversion member cover may be disposed on the substrate.

The light source may contact the conversion member cover.

The light source device may further include a light source cover covering the light source and configured to block light emitted from the light source.

The light source cover may include a light guide configured to cover a surface of the conversion member cover from which light is emitted, except for an area corresponding to the light conversion member.

The light conversion member may be disposed on a first side of the light source opposite to a second side of the light source on which the substrate is located.

The light source device may further include a reflective member covering at least a portion of the conversion member cover and configured to reflect light.

The light source may be inclined with respect to the substrate.

The light source device may further include a conversion member reflection layer between the conversion member cover and the light source cover and configured to reflect light.

The light source device may further include a conversion member reflection layer between the light conversion member and the light source cover and configured to reflect light.

The light source device may further include a substrate reflection layer between the substrate and the light source cover and configured to reflect light.

The light source device may further include a reflective block on the substrate reflection layer and configured to reflect light emitted from the light source.

The light source cover may cover only a first surface of the light source.

The light source cover may cover at least two surfaces of the light source.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 shows the external appearance of a display apparatus according to an embodiment of the disclosure;

FIG. 2 shows an exploded view of main parts of the display apparatus shown in FIG. 1;

FIG. 3 shows a light source device shown in FIG. 2;

FIG. 4 shows a cross section taken along line A-A indicated in FIG. 3;

FIG. 5 schematically shows the path of light emitted from the light source shown in FIG. 4;

FIG. 6 shows a light source device according to another embodiment of the disclosure;

FIG. 7 shows a cross section taken along line B-B indicated in FIG. 6;

FIG. 8 schematically shows the path of light emitted from the light source shown in FIG. 7;

disclosure;

FIG. 9 shows a light source device according to another embodiment of the FIG. 10 shows a cross section taken along line C-C indicated in FIG. 9;

FIG. 11 schematically shows the path of light emitted from the light source shown in FIG. 10;

FIG. 12 is a diagram showing a light source module according to another embodiment of the disclosure;

FIG. 13 shows a cross section taken along line D-D indicated in FIG. 12;

FIG. 14 schematically shows the path of light emitted from a light source shown in FIG. 13;

FIG. 15 is a diagram showing a light source module according to another embodiment of the disclosure;

FIG. 16 shows a cross section taken along line E-E indicated in FIG. 15;

FIG. 17 schematically shows the path of light emitted from a light source shown in FIG. 16;

FIG. 18 is a diagram showing a light source module according to another embodiment of the disclosure;

FIG. 19 shows a cross section taken along line F-F indicated in FIG. 18;

FIG. 20 is a diagram showing a light source module according to another embodiment of the disclosure;

FIG. 21 shows a cross section taken along line G-G indicated in FIG. 20;

FIG. 22 is a diagram showing a light source module according to another embodiment of the disclosure;

FIG. 23 shows a cross section taken along line H-H indicated in FIG. 22;

FIG. 24 shows a cross section of a light source module according to another embodiment of the disclosure;

FIG. 25 shows a cross section of a light source module according to another embodiment of the disclosure;

FIG. 26 shows a cross section of a light source module according to another embodiment of the disclosure;

FIG. 27 shows a cross section of a light source module according to another embodiment of the disclosure; and

FIG. 28 is an exploded view showing main parts of a display apparatus according to another embodiment of the disclosure.

### DETAILED DESCRIPTION

Embodiments set forth herein are not representative of the full technical spirit of the disclosure, so it may be understood that they may be replaced with various equivalents and modifications.

In the following description, it is to be understood that the singular forms “a,” “an,” and “the” include plural references unless the context clearly dictates otherwise. Unrelated parts are excluded to make the description of the disclosure clear and the sizes of components are exaggerated for clarity.

As is traditional in the field, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of embodiments may be physically separated into two or more interacting and discrete blocks, units and/or modules without departing from the present scope. Further, the blocks, units and/or modules of embodiments may be physically combined into more complex blocks, units and/or modules without departing from the present scope.

It will be further understood that the terms “include”, “comprise” and/or “have” when used in this specification, specify the presence of stated features, integers, steps, operations, elements, and/or components, but do not preclude the presence or addition of one or more other features, integers, steps, operations, elements, and/or components thereof.

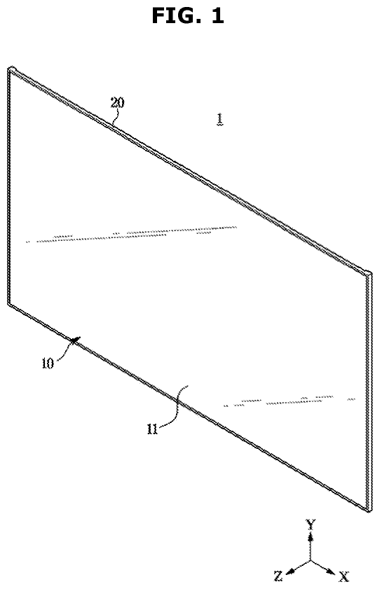

The directions of front, rear, upper, lower, left, and right will be referred to throughout the specification based on the directions shown in FIG. 1 of the accompanying drawings. In FIG. 1, the X-axis, Y-axis, and Z-axis directions are shown perpendicular to each other, in which the X-axis refers to the left-right direction of the display apparatus, the Y-axis direction refers to the up-down direction of the display apparatus, and the Z-axis direction refers to the front-to-back direction of the display apparatus.

Hereinafter, exemplary embodiments according to the disclosure will be described in detail with reference to the accompanying drawings.

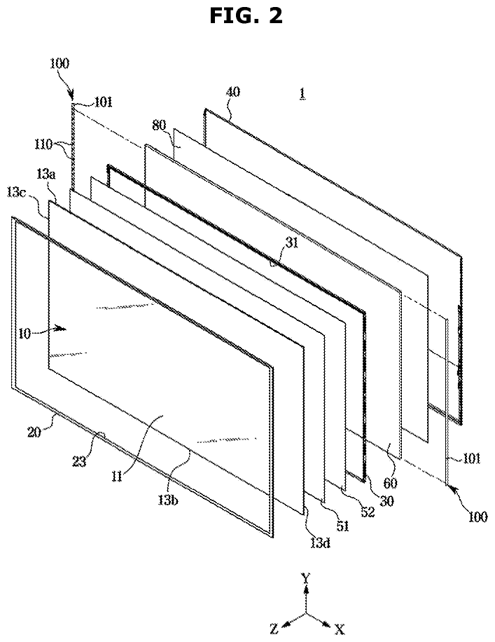

FIG. 1 shows the external appearance of a display apparatus according to an embodiment of the disclosure. FIG. 2 shows an exploded view of main parts of the display apparatus shown in FIG. 1.

Hereinafter, a display apparatus according to an embodiment of the disclosure will be described with reference to FIGS. 1 and 2.

The display apparatus 1 includes a display panel 10 on which an image is displayed, a backlight unit disposed at the rear of the display panel 10 to provide light to the display panel 10, and a chassis assembly for supporting the backlight unit and the display panel 10.

The chassis assembly includes a rear chassis 40 provided to support the backlight unit, a front chassis 20 provided at the front of the rear chassis 40 to support the display panel 10, and a middle mold 30 coupled between the front chassis 20 and the rear chassis 40.

The display panel 10 includes a TFT substrate in which TFTs are formed in a matrix form, a color filter substrate that is coupled in line with the TFT substrate, and liquid crystal injected between the TFT substrate and the color filter substrate and changing in optical properties according to change in voltage or temperature.

The display panel 10 may have a front surface 11 on which an image is displayed, a rear surface formed on the opposite side of the front surface 11, and four side surfaces 13a, 13b, 13c, and 13d on the upper, lower, left, and right sides thereof.

The backlight unit may be disposed at the rear of the display panel 10 and may emit light toward the display panel 10. The backlight unit may include a light source device 100 including a light source module 110 and a substrate 101 on which the light source module 110 is mounted, and optical members disposed on the path of light emitted from the light source module 110.

The light source device 100 may be arranged to correspond to at least one side surface of the display panel 10. Specifically, as shown in FIG. 2, the light source device 100 may be arranged to correspond to the left side surface 13c and the right side surface 13d of the display panel 10. However, the number and location of the light source device 100 is not limited thereto. That is, unlike the disclosed embodiment, the light source device 100 may be disposed to correspond to the upper side surface 13a and the lower side surface 13b of the display panel 10, or may be disposed to correspond to the four side surfaces 13a, 13b, 13c, and 13d, or may be disposed to correspond to only one of the four side surfaces 13a, 13b, 13c, and 13d.

The optical members may be disposed on the path of light emitted from the light source module 110 to guide the direction of light or improve optical characteristics. The optical members may include a light guide plate 60 that guides the light emitted from the light source module 110 toward the display panel 10, a reflective plate 80 that reflects light emitted from the light source module 110 or light exiting backward from the light guide plate 60, and optical sheets 51 and 52 that improve optical characteristics, such as brightness improvement.

The optical sheets 51 and 52 may be disposed at the front of the light guide plate 60 to improve optical characteristics of the light emitted from the light guide plate 60. The optical sheets 51 and 52 may include a prism sheet that improves brightness e by condensing light, a protection sheet that protects other optical sheets from external impact or inflow of foreign substances, and a reflective polarizing sheet (dual brightness enhancement film, DBEF) that improves brightness by reflecting one polarization and transmitting other polarization

The rear chassis 40 may be disposed at the rear of the backlight unit. The rear chassis 40 may have a substantially plate shape with an edge portion bent forward. The backlight unit may be accommodated between the rear chassis 40 and the front chassis 20.

The rear chassis 40 may include a rear base portion on which the light source device 100 is installed, and rear side portions formed at the upper, lower, left, and right edges of the rear chassis 40 to be coupled to the middle mold 30.

The rear chassis 40 may serve to dissipate heat generated from heating elements, such as the light source module 110, to the outside. For this, the rear chassis 40 may be formed of various metal materials, such as aluminum and stainless steel (SUS), or plastic materials, such as acrylonitrile butadiene styrene (ABS).

The front chassis 20 may have a frame shape with an opening 23 through which the front surface 11 of the display panel 10 is exposed. The front chassis 20 may include front side portions formed on the upper, lower, left, and right edges of the front chassis 20 to be coupled to the middle mold 30, and a panel support portion protruding inward from the front side portion to support the display panel 10.

The middle mold 30 may support the display panel 10, the light guide plate 60, and the optical sheets 51 and 52 and allow the light guide plate 60 and the optical sheets 51 and 52 to be kept spaced apart from each other. The middle mold 30 may be coupled between the front chassis 20 and the rear chassis 40.

The middle mold 30 may be formed in a frame shape with an opening 31 through which light emitted from the light guide plate 60 passes. The middle mold 30 may include a frame portion to which the front chassis 20 and the rear chassis 40 are coupled, and a central protrusion portion protruding inward from the frame portion. The central protrusion portion may support the display panel 10, the light guide plate 60, and the optical sheets 51 and 52.

The light guide plate 60 according to an embodiment of the disclosure may serve to guide light emitted from the light source module 110 toward the display panel 10 while serving to improve color gamut. The light source module 110 may be located on the lateral side of the light guide plate 60. The light source module 110 may be positioned to face the side surface of the light guide plate 60. The light source module 110 may be positioned to be spaced apart from the side surface of the light guide plate 60 by a predetermined distance.

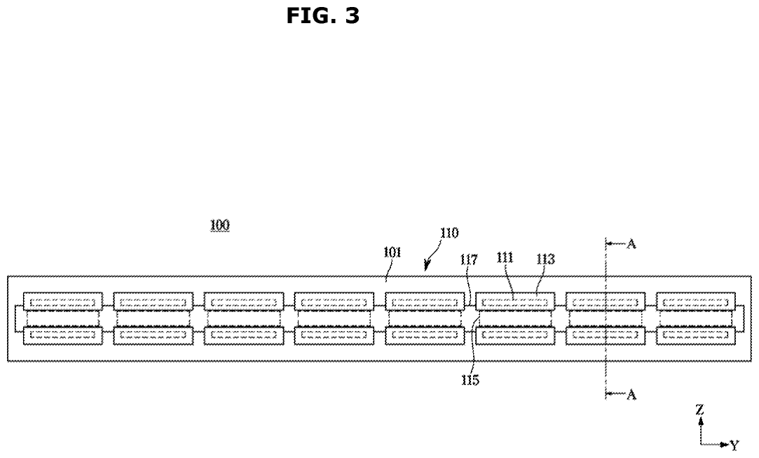

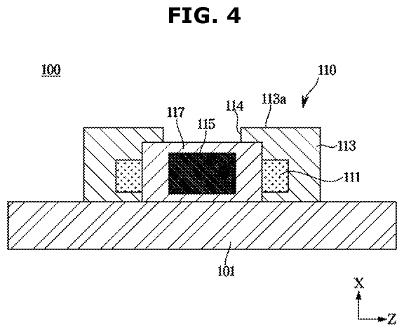

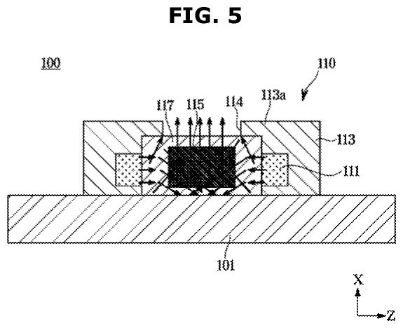

FIG. 3 shows a light source device shown in FIG. 2. FIG. 4 shows a cross section taken along line A-A indicated in FIG. 3. FIG. 5 schematically shows the path of light emitted from the light source shown in FIG. 4.

Referring to FIGS. 3 and 4, the light source device 100 may include a substrate 101 and a light source module 110 mounted on the substrate 101.

A plurality of light source modules 110 may be mounted on the substrate 101. A driving power line and the like for supplying driving power to the light source modules 110 may be formed on the substrate 101 and may be connected to a signal cable and a backlight driving circuit. The substrate 101 may be provided to reflect light emitted from the light source 111.

The light source module 110 may be provided to emit light. The light source modules 110 may be continuously arranged along the longitudinal direction (the Y-axis direction) of the substrate 101. The plurality of light source modules 110 may be arranged at predetermined intervals along the length direction of the substrate 101. The plurality of light source modules 110 may each include a light source 111, a light source cover 113, a light conversion member 115, and a conversion member cover 117.

A blue light emitting diode (LED) may be used as the light source 111. In addition, a cold cathode fluorescent lamp (CCFL) and an external electrode fluorescent lamp (EEFL) may also be used.

The light sources 111 may be provided on both sides of the light conversion member 115. The plurality of light sources 111 may be arranged to be spaced apart along the width direction of the substrate 101. The light source 111 may be provided to emit light from all surfaces other than a surface facing away from the light conversion member 115.

The light source cover 113 may be disposed on the substrate 101. The light source cover 113 may be provided to cover the light source 111.

The light source cover 113 may be provided to condense the light emitted from the light source 111 toward the light conversion member 115. That is, the light source cover 113 may be provided to block light emitted from surfaces of the light source 111 other than a surface facing the light conversion member 115. To the end, the light source cover 113 may be provided to cover the surfaces other than the surface of the light source 111 facing the light conversion member 115. The light source cover 113 may be formed of a material through which light may not pass. The light source cover 113 may be provided to electrically connect the substrate 101 and the light source 111.

The light source cover 113 may include a light guide 113a formed to cover a portion of a surface of the conversion member cover 117 from which light is emitted. Specifically, the light guide 113a may be provided to cover a portion of the light emitting surface of the conversion member cover 117 that does not correspond to the light conversion member 115. Accordingly, the light guide 113a may reflect light from the light source 111 that has not passed through the light conversion member 115 to the light conversion member 115. Accordingly, the color gamut of the display apparatus 1 may be improved.

A light exit portion 114 may be formed between the light guides 113a. Light passed through the light conversion member 115 may be emitted through the light exit portion 114.

The light conversion member 115 may be provided to improve color gamut. The light conversion member 115 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material. The luminescent material forming the phosphor is not limited thereto.

The conversion member cover 117 may be disposed on the substrate 101. The conversion member cover 117 may be provided to cover the light conversion member 115. The conversion member cover 117 may prevent the light conversion member 115 from being degraded or damaged by the light source 111, thereby preventing a decrease in functionality. The conversion member cover 117 may protect the light conversion member 115 from external foreign substances. The conversion member cover 117 may prevent the light conversion member 115 from being oxidized.

The conversion member cover 117 may be provided to allow light emitted from the light source 111 to pass therethrough. The conversion member cover 117 may be provided to allow light converted by the light conversion member 115 to pass therethrough.

Referring to FIG. 5, light emitted from the light source 111 may pass through the conversion member cover 117. Part of the light passing through the conversion member cover 117 may be reflected by the substrate 101 and then pass through the light conversion member 115. Another part of the light passing through the conversion member cover 117 may be reflected by the light guide 113a and then pass through the light conversion member 115. Another part of the light passing through the conversion member cover 117 may directly pass through the light conversion member 115 without going through any other configuration. Light passed through the light conversion member 115 may be emitted through the light exit portion 114.

With such a configuration, the display apparatus 1 according to the embodiment of the disclosure may have the light conversion member 115 provided in the light source device 100 that is implemented to improve color gamut, so that among the optical sheets 51 and 52, a sheet for improving the color gamut may be omitted, thereby simplifying the manufacturing process, reducing the unit cost of the product, and providing the display apparatus 1 with a reduced thickness.

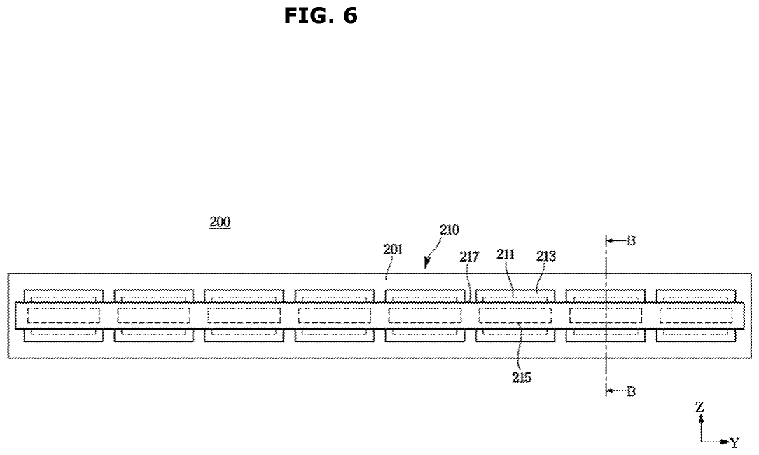

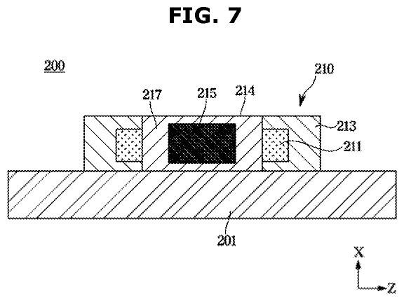

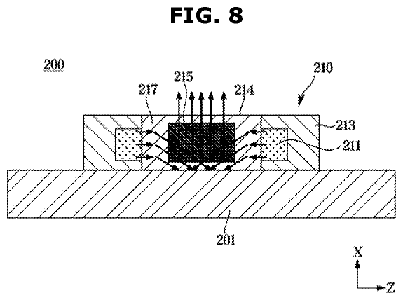

FIG. 6 shows a light source device according to another embodiment of the disclosure. FIG. 7 shows a cross section taken along line B-B indicated in FIG. 6. FIG. 8 schematically shows the path of light emitted from the light source shown in FIG. 7.

Referring to FIGS. 6 and 7, a light source device 200 may include a substrate 201 and a light source module 210 mounted on the substrate 201.

A plurality of light source modules 210 may be mounted on the substrate 201. A driving power line, and the like for supplying driving power to the light source modules 210 may be formed on the substrate 201 and may be connected to a signal cable and a backlight driving circuit. The substrate 201 may be provided to reflect light emitted from the light source 211.

The light source module 210 may be provided to emit light. The light source modules 210 may be continuously arranged along the longitudinal direction (the Y-axis direction) of the substrate 201. The plurality of light source modules 210 may be arranged at predetermined intervals along the length direction of the substrate 201. The plurality of light source modules 210 may each include a light source 211, a light source cover 213, a light conversion member 215, and a conversion member cover 217.

A blue light emitting diode (LED) may be used as the light source 211. In addition, a cold cathode fluorescent lamp (CCFL) and an external electrode fluorescent lamp (EEFL) may also be used.

The light sources 211 may be provided on both sides of the light conversion member 215. The plurality of light sources 211 may be arranged to be spaced apart along the width direction of the substrate 201. The light source 211 may be provided to emit light from all surfaces except a surface facing away from the light conversion member 215.

The light source cover 213 may be disposed on the substrate 201. The light source cover 213 may be provided to cover the light source 211.

The light source cover 213 may be provided to condense the light emitted from the light source 211 toward the light conversion member 215. That is, the light source cover 213 may be provided to block light emitted from surfaces of the light source 211 other than a surface facing the light conversion member 215. To the end, the light source cover 213 may be provided to cover the surfaces other than the surface of the light source 211 facing the light conversion member 215. The light source cover 213 may be formed of a material through which light may not pass. The light source cover 213 may be provided to electrically connect the substrate 201 and the light source 211.

The light conversion member 215 may be provided to improve color gamut. The light conversion member 215 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material. The luminescent material forming the phosphor is not limited thereto.

The conversion member cover 217 may be disposed on the substrate 201. The conversion member cover 217 may be provided to cover the light conversion member 215. The conversion member cover 217 may prevent the light conversion member 215 from being degraded or damaged by the light source 211, thereby preventing a decrease in functionality. The conversion member cover 217 may protect the light conversion member 215 from external foreign substances. The conversion member cover 217 may prevent the light conversion member 215 from being oxidized.

The conversion member cover 217 may be provided to allow light emitted from the light source 211 to pass therethrough. The conversion member cover 217 may be provided to allow light converted by the light conversion member 215 to pass therethrough.

The front surface of the conversion member cover 217 may be provided as a light exit portion 214. Light passed through the light conversion member 215 may be emitted through the light exit portion 214.

Referring to FIG. 8, light emitted from the light source 211 may pass through the conversion member cover 217. Part of the light passing through the conversion member cover 217 may be reflected by the substrate 201 and then pass through the light conversion member 215. Another part of the light passing through the conversion member cover 217 may directly pass through the light conversion member 215 without going through any other configuration. Light passed through the light conversion member 215 may be emitted through the light exit portion 214.

With such a configuration, the light source device 200 according to the embodiment of the disclosure may include the light conversion member 215 that is implemented to improve color gamut, so that a sheet for improving the color gamut may be omitted, thereby simplifying the manufacturing process, reducing the unit cost of the product, and providing the display apparatus 1 with a reduced thickness.

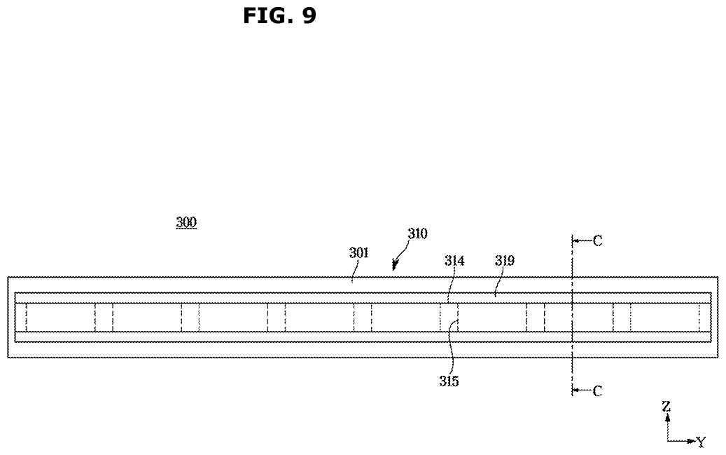

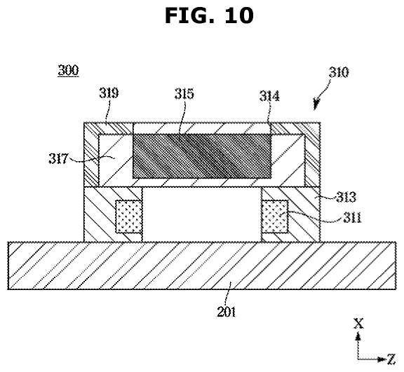

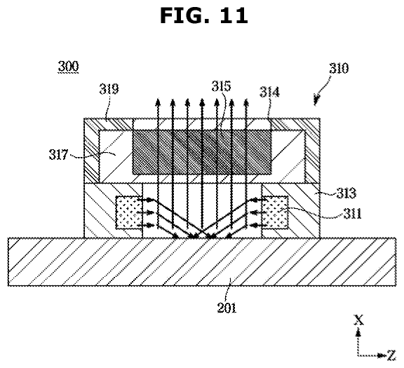

FIG. 9 shows a light source device according to another embodiment of the disclosure. FIG. 10 shows a cross section taken along line C-C indicated in FIG. 9. FIG. 11 schematically shows the path of light emitted from the light source shown in FIG. 10.

Referring to FIGS. 9 and 10, a light source device 300 may include a substrate 301 and a light source module 310 mounted on the substrate 301.

A plurality of light source modules 310 may be mounted on the substrate 301. A driving power line, and the like for supplying driving power to the light source modules 310 may be formed on the substrate 301 and may be connected to a signal cable and a backlight driving circuit. The substrate 301 may be provided to reflect light emitted from the light source 311.

The light source module 310 may be provided to emit light. The light source modules 310 may be continuously arranged along the longitudinal direction (the Y-axis direction) of the substrate 301. The plurality of light source modules 310 may be arranged at predetermined intervals along the length direction of the substrate 301. The plurality of light source modules 310 may each include a light source 311, a light source cover 313, a light conversion member 315, and a conversion member cover 317.

A blue light emitting diode (LED) may be used as the light source 311. In addition, a cold cathode fluorescent lamp (CCFL) and an external electrode fluorescent lamp (EEFL) may also be used.

The light source 311 may be provided as a plurality of light sources 311 to be symmetrical with respect to approximately the center of the light source module 310. The plurality of light sources 311 may be arranged to be spaced apart along the width direction of the substrate 301. The light source 311 may be provided to emit light from all surfaces other than one surface thereof.

The light source cover 313 may be disposed on the substrate 301. The light source cover 313 may be provided to cover the light source 311.

The light source cover 313 may be provided to condense the light emitted from the light source 311 toward the light conversion member 315. That is, the light source cover 313 may be provided to block light emitted from surfaces of the light source 311 other than a surface from which light is emitted. The light source 311 may be provided to emit light toward the center of the light source module 310. To the end, the light source cover 313 may be provided to cover surfaces other than a surface of the light source 311 facing the center of the light source module 310. The light source cover 313 may be formed of a material through which light may not pass. The light source cover 313 may be provided to electrically connect the substrate 301 and the light source 311.

The light conversion member 315 may be provided to improve color gamut. The light conversion member 315 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material. The luminescent material forming the phosphor is not limited thereto.

The conversion member cover 317 may be disposed on the other side of the light source 311 opposite to one side on which the substrate 301 is disposed. The conversion member cover 317 may be provided to cover the light conversion member 315. The conversion member cover 317 may prevent the light conversion member 315 from being degraded or damaged by the light source 311, thereby preventing a decrease in functionality. The conversion member cover 317 may protect the light conversion member 315 from external foreign substances. The conversion member cover 317 may prevent the light conversion member 315 from being oxidized.

The conversion member cover 317 may be provided to allow light emitted from the light source 311 to pass therethrough. The conversion member cover 317 may be provided to allow light converted by the light conversion member 315 to pass therethrough.

At least a portion of the front surface of the conversion member cover 317 may be provided as a light exit portion 314. Light passed through the light conversion member 315 may be emitted through the light exit portion 314.

The light source module 310 may include a reflective member 319 provided to cover at least a portion of the conversion member cover 317. The reflective member 319 may be provided to cover outer surfaces of the conversion member cover 317 other than an outer surface onto which light is incident and the light exit portion 314.

The reflective member 319 may be configured to reflect light. The reflective member 319 may guide light passed through the light conversion member 315 to be emitted through the light exit portion 314. The reflective member 319 may guide light incident onto the conversion member cover 317 to pass through the light conversion member 315. The reflective member 319 may prevent light that has not passed through the light conversion member 315 from exiting the conversion member cover 317. The reflective member 319 may prevent light from exiting through other portions than the light exit portion 314 of the conversion member cover 317.

Referring to FIG. 11, part of light emitted from the light source 311 may be reflected by the substrate 101 and then introduced into the conversion member cover 317. Part of the light introduced into the conversion member cover 317 may pass through the light conversion member 315. Another part of the light introduced into the conversion member cover 317 may not pass through the light conversion member 315, but the light may be guided by the reflective member 319 to thereby pass through the light conversion member 315. Light passed through the light conversion member 315 may be emitted through the light exit portion 314.

With such a configuration, the light source device 300 according to the embodiment of the disclosure may include the light conversion member 315 that is implemented to improve color gamut, so that a sheet for improving the color gamut may be omitted, thereby simplifying the manufacturing process, reducing the unit cost of the product, and providing the display apparatus 1 with a reduced thickness.

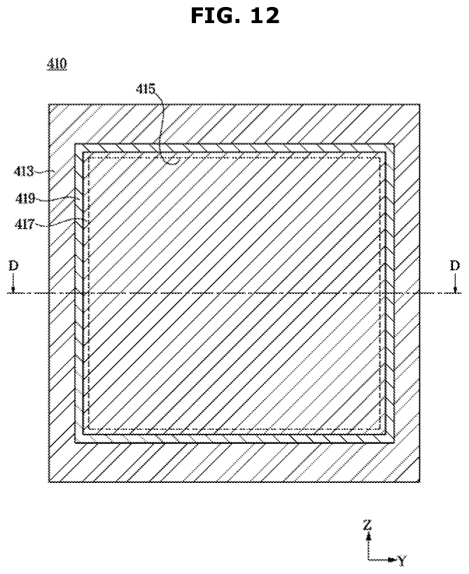

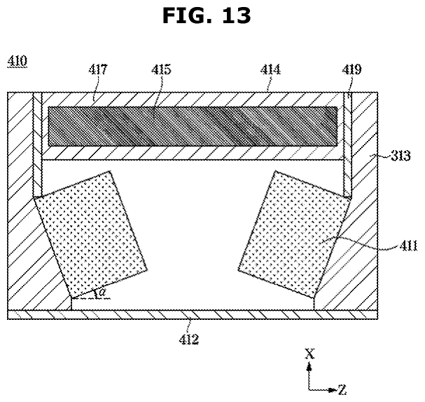

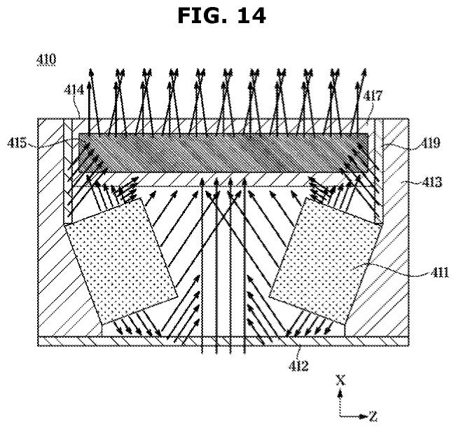

FIG. 12 is a diagram showing a light source module according to another embodiment of the disclosure. FIG. 13 shows a cross section taken along line D-D indicated in FIG. 12. FIG. 14 schematically shows the path of light emitted from a light source shown in FIG. 13.

Referring to FIGS. 12 and 14, a light source module 410 according to another embodiment of the disclosure will be described. The light source module 410 shown in FIGS. 12 to 14 may be applied to the display apparatus 1 shown in FIGS. 3 to 5.

Referring to FIGS. 12 and 13, the light source module 410 may be provided to emit light. The light source module 410 may include a light source 411, a light source cover 413, a light conversion member 415, and a conversion member cover 417.

A blue light emitting diode (LED) may be used as the light source 411. In addition, a cold cathode fluorescent lamp (CCFL) and an external electrode fluorescent lamp (EEFL) may also be used.

The light source 411 may be provided as a plurality of light sources 411 to be symmetrical with respect to approximately the center of the light source module 410. The light source 411 may be provided to emit light from all surfaces other than one surface thereof.

The light source cover 413 may be provided to cover the light source 411.

The light source module 410 may include a substrate reflection layer 412 disposed between the substrate 101 and the light source cover 413. The substrate reflection layer 412 may be configured to reflect light. The substrate reflection layer 412 may be attached to the substrate 101 of the embodiment shown in FIGS. 3 to 5. The substrate reflection layer 412 may be provided to electrically connect the light source 411 and the substrate 101.

The light source 411 may be obliquely disposed with respect to a direction in which the substrate reflection layer 412 extends. The light source 411 may be disposed such that one side that emits light is inclined toward the light conversion member 415. With such a configuration, light emitted from the light source module 410 may be condensed.

The light source cover 413 may be provided to condense the light emitted from the light source 411 toward the light conversion member 415. The light source cover 413 may be in contact with a surface of the light source 411 to support the light source 411. The light source cover 413 may be provided to block light emitted from the light source 411. The light source cover 413 may be formed of a material through which light may not pass. The light source cover 413 may be provided to electrically connect the substrate 401 and the light source 411.

The light conversion member 415 may be provided to improve color gamut. The light conversion member 415 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material. The luminescent material forming the phosphor is not limited thereto.

The conversion member cover 417 may be disposed on the other side of the light source 411 opposite to one side on which the substrate reflection layer 412 is disposed. The conversion member cover 417 may be provided to cover the light conversion member 415. The conversion member cover 417 may prevent the light conversion member 415 from being degraded or damaged by the light source 411, thereby preventing a decrease in functionality. The conversion member cover 417 may protect the light conversion member 415 from external foreign substances. The conversion member cover 417 may prevent the light conversion member 415 from being oxidized.

The conversion member cover 417 may be provided to allow light emitted from the light source 411 to pass therethrough. The conversion member cover 417 may be provided to allow light converted by the light conversion member 415 to pass therethrough.

At least a portion of the front surface of the conversion member cover 417 may be provided as a light exit portion 414. Light passed through the light conversion member 415 may be emitted through the light exit portion 414.

The light source module 410 may include a reflective member 419 provided to cover at least a portion of the conversion member cover 417. The reflective member 419 may be provided to cover outer surfaces of the conversion member cover 417, other than an outer surface onto which light is incident and the light exit portion 414. The reflective member 419 may be disposed between the conversion member cover 417 and the light source cover 413.

The reflective member 419 may be configured to reflect light. The reflective member 419 may guide Light passed through the light conversion member 415 to be emitted through the light exit portion 414. The reflective member 419 may guide light incident onto the conversion member cover 417 to pass through the light conversion member 415. The reflective member 419 may prevent light that has not passed through the light conversion member 415 from exiting the conversion member cover 417. The reflective member 419 may prevent light from exiting through other portions than the light exit portion 414 of the conversion member cover 417.

Referring to FIG. 14, light emitted from the light source 411 may be reflected by the substrate reflection layer 412 and then introduced into the conversion member cover 417. Part of the light introduced into the conversion member cover 417 may pass through the light conversion member 415. Another part of the light introduced into the conversion member cover 417 may not pass through the light conversion member 415, but the light may be guided by the reflective member 419 to thereby pass through the light conversion member 415. Light passed through the light conversion member 415 may be emitted through the light exit portion 414.

With such a configuration, the light source module 410 according to the embodiment of the disclosure may include the light conversion member 415 that is implemented to improve color gamut, so that a sheet for improving the color gamut is omitted, thereby simplifying the manufacturing process, reducing the unit cost of the product, and providing the display apparatus 1 with a reduced thickness.

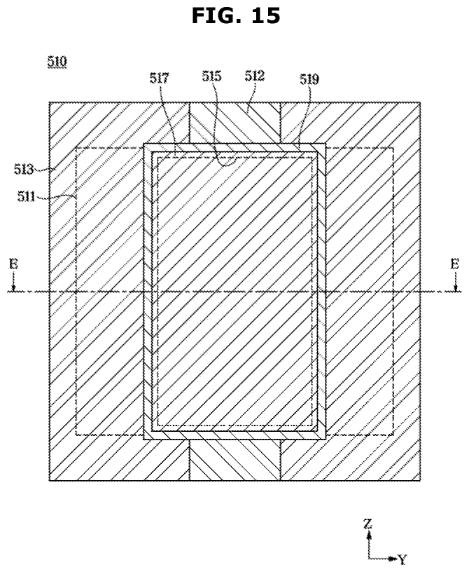

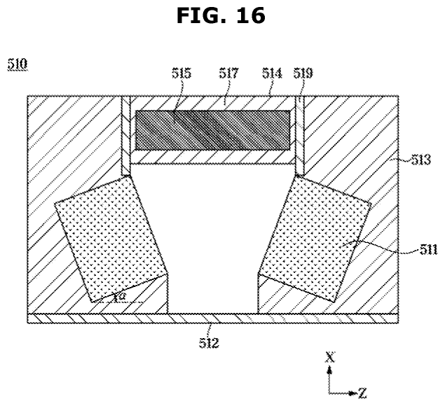

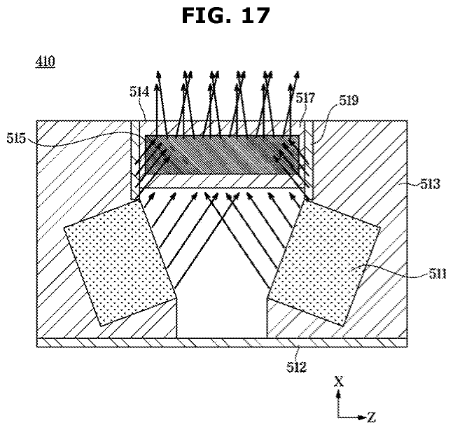

FIG. 15 is a diagram showing a light source module according to another embodiment of the disclosure. FIG. 16 shows a cross section taken along line E-E indicated in FIG. 15. FIG. 17 schematically shows the path of light emitted from a light source shown in FIG. 16.

Referring to FIGS. 15 and 17, a light source module 510 according to another embodiment of the disclosure will be described. The light source module 510 shown in FIGS. 15 to 17 may be applied to the display apparatus 1 shown in FIGS. 3 to 5.

Referring to FIGS. 15 to 17, the light source module 510 may be provided to emit light. The light source module 510 may include a light source 511, a light source cover 513, a light conversion member 515, and a conversion member cover 517.

A blue light emitting diode (LED) may be used as the light source 511. In addition, a cold cathode fluorescent lamp (CCFL) and an external electrode fluorescent lamps (EEFL) may also be used.

The light source 511 may be provided as a plurality of light sources 511 to be symmetrical with respect to approximately the center of the light source module 510. The light source 511 may be provided to emit light from all surfaces other than one surface thereof.

The light source cover 513 may be provided to cover the light source 511.

The light source module 510 may include a substrate reflection layer 512 disposed between the substrate 101 and the light source cover 513. The substrate reflection layer 512 may be configured to reflect light. The substrate reflection layer 512 may be attached to the substrate 101 of the embodiment shown in FIGS. 3 to 5. The substrate reflection layer 512 may be provided to electrically connect the light source 511 and the substrate 101.

The light source 511 may be obliquely disposed with respect to a direction in which the substrate reflection layer 512 extends. The light source 511 may be disposed such that one side that emits light is inclined toward the light conversion member 515. With such a configuration, light emitted from the light source module 510 may be condensed.

The light source cover 513 may be provided to condense the light emitted from the light source 511 toward the light conversion member 515. That is, the light source cover 513 may be provided to block light emitted from surfaces of the light source 511 other than a surface facing the light conversion member 515. To the end, the light source cover 513 may be provided to cover the surfaces other than the surface of the light source 511 facing the light conversion member 515. The light source cover 513 may be formed of a material through which light may not pass. The light source cover 513 may be provided to electrically connect the substrate 501 and the light source 511. The light source cover 513 may be in contact with a surface of the light source 511 to support the light source 511.

The light conversion member 515 may be provided to improve color gamut. The light conversion member 515 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material. The luminescent material forming the phosphor is not limited thereto.

The conversion member cover 517 may be disposed on the other side of the light source 511 opposite to one side on which the substrate reflection layer 512 is disposed. The conversion member cover 517 may be provided to cover the light conversion member 515.

The conversion member cover 517 may prevent the light conversion member 515 from being degraded or damaged by the light source 511, thereby preventing a decrease in functionality. The conversion member cover 517 may protect the light conversion member 515 from external foreign substances. The conversion member cover 517 may prevent the light conversion member 515 from being oxidized.

The conversion member cover 517 may be provided to allow light emitted from the light source 511 to pass therethrough. The conversion member cover 517 may be provided to allow light converted by the light conversion member 515 to pass therethrough.

At least a portion of the front surface of the conversion member cover 517 may be provided as a light exit portion 514. Light passed through the light conversion member 515 may be emitted through the light exit portion 514.

The light source module 510 may include a reflective member 519 provided to cover at least a portion of the conversion member cover 517. The reflective member 519 may be provided to cover outer surfaces of the conversion member cover 517, other than an outer surface onto which light is incident and the light exit portion 514. The reflective member 519 may be disposed between the conversion member cover 517 and the light source cover 513.

The reflective member 519 may be configured to reflect light. The reflective member 519 may guide Light passed through the light conversion member 515 to be emitted through the light exit portion 514. The reflective member 519 may guide light incident onto the conversion member cover 517 to pass through the light conversion member 515. The reflective member 519 may prevent light that has not passed through the light conversion member 515 from exiting the conversion member cover 517. The reflective member 519 may prevent light from exiting through other portions than the light exit portion 514 of the conversion member cover 517.

Referring to FIG. 17, light emitted from the light source 511 may be reflected by the substrate reflection layer 512 and then introduced into the conversion member cover 517. Part of the light introduced into the conversion member cover 517 may pass through the light conversion member 515. Another part of the light introduced into the conversion member cover 517 may not pass through the light conversion member 515, but the light may be guided by the reflective member 519 to thereby pass through the light conversion member 515. Light passed through the light conversion member 515 may be emitted through the light exit portion 514.

With such a configuration, the light source module 510 according to the embodiment of the disclosure may include the light conversion member 515 that is implemented to improve color gamut, so that a sheet for improving the color gamut is omitted, thereby simplifying the manufacturing process, reducing the unit cost of the product, and providing the display apparatus 1 with a reduced thickness.

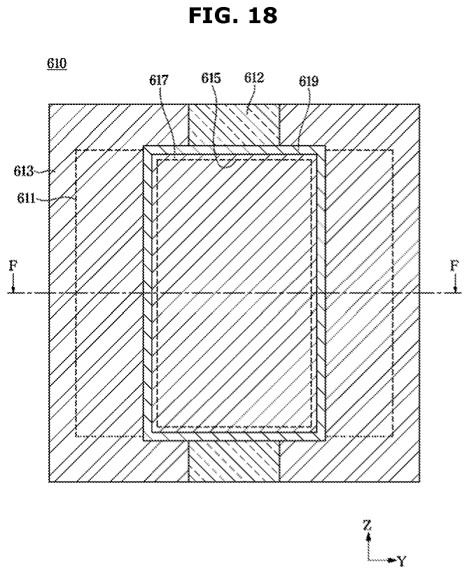

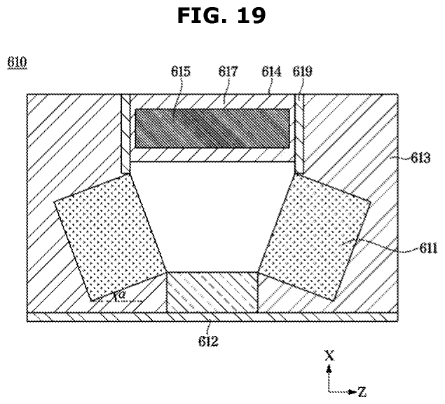

FIG. 18 is a diagram showing a light source module according to another embodiment of the disclosure. FIG. 19 shows a cross section taken along line F-F indicated in FIG. 18.

Referring to FIGS. 18 and 19, a light source module 610 according to another embodiment of the disclosure will be described. The light source module 610 shown in FIGS. 18 and 19 may be applied to the display apparatus 1 shown in FIGS. 3 to 5.

Referring to FIGS. 18 and 19, the light source module 610 may be provided to emit light. The light source module 610 may include a light source 611, a light source cover 613, a light conversion member 615, and a conversion member cover 617.

A blue light emitting diode (LED) may be used as the light source 611. In addition, a cold cathode fluorescent lamp (CCFL) and an external electrode fluorescent lamp (EEFL) may also be used.

The light source 611 may be provided as a plurality of light sources 611 to be symmetrical with respect to approximately the center of the light source module 610. The light source 611 may be provided to emit light from all surfaces other than one surface thereof.

The light source cover 613 may be provided to cover the light source 611.

The light source module 610 may include a substrate reflection layer 612 disposed between the substrate 101 and the light source cover 613. The substrate reflection layer 612 may be configured to reflect light. The substrate reflection layer 612 may be attached to the substrate 101 of the embodiment shown in FIGS. 3 to 5. The substrate reflection layer 612 may be provided to electrically connect the light source 611 and the substrate 101.

The light source 611 may be obliquely disposed with respect to a direction in which the substrate reflection layer 612 extends. The light source 611 may be disposed such that one side that emits light is inclined toward the light conversion member 615. With such a configuration, light emitted from the light source module 610 may be condensed.

The light source cover 613 may be provided to condense the light emitted from the light source 611 toward the light conversion member 615. That is, the light source cover 613 may be provided to block light emitted from surfaces of the light source 611 other than a surface facing the light conversion member 615. To the end, the light source cover 613 may be provided to cover the surfaces other than the surface of the light source 611 facing the light conversion member 615. The light source cover 613 may be formed of a material through which light may not pass. The light source cover 613 may be provided to electrically connect the substrate 601 and the light source 611. The light source cover 613 may be in contact with a surface of the light source 611 to support the light source 611.

The light conversion member 615 may be provided to improve color gamut. The light conversion member 615 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material. The luminescent material forming the phosphor is not limited thereto.

The conversion member cover 617 may be disposed on the other side of the light source 611 opposite to one side on which the substrate reflection layer 612 is disposed. The conversion member cover 617 may be provided to cover the light conversion member 615. The conversion member cover 617 may prevent the light conversion member 615 from being degraded or damaged by the light source 611, thereby preventing a decrease in functionality. The conversion member cover 617 may protect the light conversion member 615 from external foreign substances. The conversion member cover 617 may prevent the light conversion member 615 from being oxidized.

The conversion member cover 617 may be provided to allow light emitted from the light source 611 to pass therethrough. The conversion member cover 617 may be provided to allow light converted by the light conversion member 615 to pass therethrough.

At least a portion of the front surface of the conversion member cover 617 may be provided as a light exit portion 614. Light passed through the light conversion member 615 may be emitted through the light exit portion 614.

The light source module 610 may include a reflective member 619 provided to cover at least a portion of the conversion member cover 617. The reflective member 619 may be provided to cover outer surfaces of the conversion member cover 617, other than an outer surface onto which light is incident and the light exit portion 614. The reflective member 619 may be disposed between the conversion member cover 617 and the light source cover 613.

The reflective member 619 may be configured to reflect light. The reflective member 619 may guide Light passed through the light conversion member 615 to be emitted through the light exit portion 614. The reflective member 619 may guide light incident onto the conversion member cover 617 to pass through the light conversion member 615. The reflective member 619 may prevent light that has not passed through the light conversion member 615 from exiting the conversion member cover 617. The reflective member 619 may prevent light from exiting through other portions than the light exit portion 614 of the conversion member cover 617.

The light source module 610 may include a reflective block 618. The reflective block 618 may be provided to reflect light emitted from the light source 611. Part of the light emitted from the light source 611 may be reflected from the reflective block 618 to the light conversion member 615. The reflective block 618 may include a material with a higher reflectivity than the substrate reflection layer 612.

With such a configuration, the light source module 600 according to the embodiment of the disclosure may include the light conversion member 615 that is implemented to improve color gamut, so that a sheet for improving the color gamut is omitted, thereby simplifying the manufacturing process, reducing the unit cost of the product, and providing the display apparatus 1 with a reduced thickness.

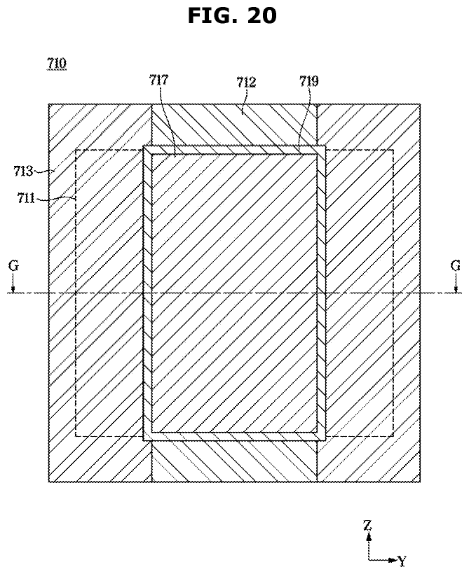

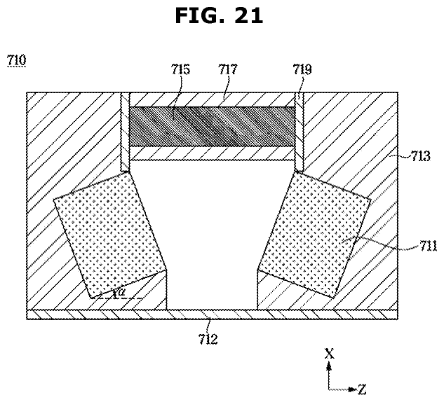

FIG. 20 is a diagram showing a light source module according to another embodiment of the disclosure. FIG. 21 shows a cross section taken along line G-G indicated in FIG. 20.

Referring to FIGS. 20 and 212, a light source module 710 according to another embodiment of the disclosure will be described. The light source module 710 shown in FIGS. 20 and 21 may be applied to the display apparatus 1 shown in FIGS. 3 to 5.

Referring to FIGS. 20 and 21, the light source module 710 may be provided to emit light. The light source module 710 may include a light source 711, a light source cover 713, a light conversion member 715, and a conversion member cover 717.

A blue light emitting diode (LED) may be used as the light source 711. In addition, a cold cathode fluorescent lamp (CCFL) and an external electrode fluorescent lamp (EEFL) may also be used.

The light source 711 may be provided as a plurality of light sources 711 to be symmetrical with respect to approximately the center of the light source module 710. The light source 711 may be provided to emit light from all surfaces other than one surface thereof.

The light source cover 713 may be provided to cover the light source 711.

The light source module 710 may include a substrate reflection layer 712 disposed between the substrate 101 and the light source cover 713. The substrate reflection layer 712 may be configured to reflect light. The substrate reflection layer 712 may be attached to the substrate 101 of the embodiment shown in FIGS. 3 to 5. The substrate reflection layer 712 may be provided to electrically connect the light source 711 and the substrate 101.

The light source 711 may be obliquely disposed with respect to a direction in which the substrate reflection layer 712 extends. The light source 711 may be disposed such that one side that emits light is inclined toward the light conversion member 715. With such a configuration, light emitted from the light source module 710 may be condensed.

The light source cover 713 may be provided to condense the light emitted from the light source 711 toward the light conversion member 715. That is, the light source cover 713 may be provided to block light emitted from surfaces of the light source 711 other than a surface facing the light conversion member 715. To the end, the light source cover 713 may be provided to cover the surfaces other than the surface of the light source 711 facing the light conversion member 715. The light source cover 713 may be formed of a material through which light may not pass. The light source cover 713 may be provided to electrically connect the substrate 701 and the light source 711. The light source cover 713 may be in contact with a surface of the light source 711 to support the light source 711.

The light conversion member 715 may be provided to improve color gamut. The light conversion member 715 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material. The luminescent material forming the phosphor is not limited thereto.

The conversion member cover 717 may be disposed on the other side of the light source 711 opposite to one side on which the substrate reflection layer 712 is disposed. The conversion member cover 717 may be provided to cover at least a portion of the light conversion member 715. The conversion member cover 717 may be provided to cover a light incident surface and a light exit surface of the light conversion member 715.

The conversion member cover 717 may prevent the light conversion member 715 from being degraded or damaged by the light source 711, thereby preventing a decrease in functionality. The conversion member cover 717 may protect the light conversion member 715 from external foreign substances. The conversion member cover 717 may prevent the light conversion member 715 from being oxidized.

The conversion member cover 717 may be provided to allow light emitted from the light source 711 to pass therethrough. The conversion member cover 717 may be provided to allow light converted by the light conversion member 715 to pass therethrough.

At least a portion of the front surface of the conversion member cover 717 may be provided as a light exit portion 714. Light passed through the light conversion member 715 may be emitted through the light exit portion 714.

The light source module 710 may include a reflective member 719 provided to cover at least a portion of the light conversion member 715. The reflective member 719 may be provided to cover outer surfaces of the light conversion member 715, other than the light incident surface and the light exit surface. The reflective member 719 may be disposed between the light conversion member 715 and the light source cover 713. The reflective member 719 may prevent light from exiting through surfaces of the light conversion member 715 other than the light exit portion 714. As the reflective member 719 is provided to contact the outer surface of the light conversion member 715, loss of light may be prevented.

The reflective member 719 may be configured to reflect light. The reflective member 719 may guide light passed through the light conversion member 715 to be emitted through the light exit portion 714. The reflective member 719 may guide light incident through the conversion member cover 717 to pass through the light conversion member 715.

With such a configuration, the light source module 700 according to the embodiment of the disclosure may include the light conversion member 715 that is implemented to improve color gamut, so that a sheet for improving the color gamut is omitted, thereby simplifying the manufacturing process, reducing the unit cost of the product, and providing the display apparatus 1 with a reduced thickness.

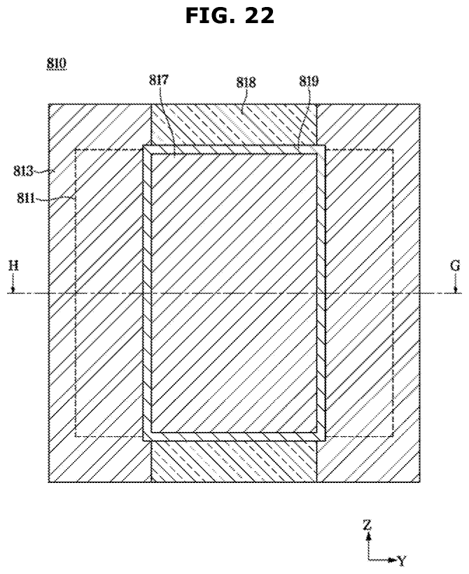

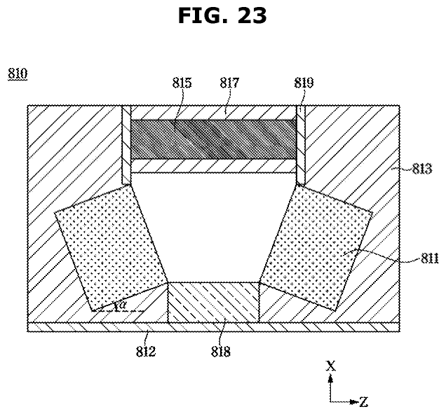

FIG. 22 is a diagram showing a light source module according to another embodiment of the disclosure. FIG. 23 shows a cross section taken along line H-H indicated in FIG. 22.

Referring to FIGS. 22 and 23, a light source module 810 according to another embodiment of the disclosure will be described. The light source module 810 shown in FIGS. 22 and 23 may be applied to the display apparatus 1 shown in FIGS. 3 to 5.

Referring to FIGS. 22 and 23, the light source module 810 may be provided to emit light. The light source module 810 may include a light source 811, a light source cover 813, a light conversion member 815, and a conversion member cover 817.

A blue light emitting diode (LED) may be used as the light source 811. In addition, a cold cathode fluorescent lamp (CCFL) and an external electrode fluorescent lamp (EEFL) may also be used.

The light source 811 may be provided as a plurality of light sources 811 to be symmetrical with respect to approximately the center of the light source module 810. The light source 811 may be provided to emit light from all surfaces other than one surface thereof.

The light source cover 813 may be provided to cover the light source 811.

The light source module 810 may include a substrate reflection layer 812 disposed between the substrate 101 and the light source cover 813. The substrate reflection layer 812 may be configured to reflect light. The substrate reflection layer 812 may be attached to the substrate 101 of the embodiment shown in FIGS. 3 to 5. The substrate reflection layer 812 may be provided to electrically connect the light source 811 and the substrate 101.

The light source 811 may be obliquely disposed with respect to a direction in which the substrate reflection layer 812 extends. The light source 811 may be disposed such that one side that emits light is inclined toward the light conversion member 815. With such a configuration, light emitted from the light source module 810 may be condensed.

The light source cover 813 may be provided to condense the light emitted from the light source 811 toward the light conversion member 815. That is, the light source cover 813 may be provided to block light emitted from surfaces of the light source 811 other than a surface facing the light conversion member 815. To the end, the light source cover 813 may be provided to cover the surfaces other than the surface of the light source 811 facing the light conversion member 815. The light source cover 813 may be formed of a material through which light may not pass. The light source cover 813 may be provided to electrically connect the substrate 801 and the light source 811. The light source cover 813 may be in contact with a surface of the light source 811 to support the light source 811.

The light conversion member 815 may be provided to improve color gamut. The light conversion member 815 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material. The luminescent material forming the phosphor is not limited thereto.

The conversion member cover 817 may be disposed on the other side of the light source 811 opposite to one side on which the substrate reflection layer 812 is disposed. The conversion member cover 817 may be provided to cover at least a portion of the light conversion member 815. The conversion member cover 817 may be provided to cover a light incident surface and a light exit surface of the light conversion member 815.

The conversion member cover 817 may prevent the light conversion member 815 from being degraded or damaged by the light source 811, thereby preventing a decrease in functionality. The conversion member cover 817 may protect the light conversion member 815 from external foreign substances. The conversion member cover 817 may prevent the light conversion member 815 from being oxidized.

The conversion member cover 817 may be provided to allow light emitted from the light source 811 to pass therethrough. The conversion member cover 817 may be provided to allow light converted by the light conversion member 815 to pass therethrough.

At least a portion of the front surface of the conversion member cover 817 may be provided as a light exit portion 814. Light passed through the light conversion member 815 may be emitted through the light exit portion 814.

The light source module 810 may include a reflective member 819 provided to cover at least a portion of the light conversion member 815. The reflective member 819 may be provided to cover outer surfaces of the light conversion member 815, other than the light incident surface and the light exit surface. The reflective member 819 may be disposed between the light conversion member 815 and the light source cover 813. The reflective member 819 may prevent light from exiting through surfaces other than the light exit portion 814 of the light conversion member 815. As the reflective member 819 is provided to contact the outer surface of the light conversion member 815, loss of light may be prevented.

The reflective member 819 may be configured to reflect light. The reflective member 819 may guide light passed through the light conversion member 815 to be emitted through the light exit portion 814. The reflective member 819 may guide light incident onto the conversion member cover 817 to pass through the light conversion member 815.

The light source module 810 may include a reflection block 818. The reflection block 818 may be provided to reflect light emitted from the light source 811. Part of the light emitted from the light source 811 may be reflected from the reflection block 818 to the light conversion member 815. The reflection block 818 may include a material with a higher reflectivity than the substrate reflection layer 812.

With such a configuration, the light source module 800 according to the embodiment of the disclosure may include the light conversion member 815 that is implemented to improve color gamut, so that a sheet for improving the color gamut is omitted, thereby simplifying the manufacturing process, reducing the unit cost of the product, and providing the display apparatus 1 with a reduced thickness.

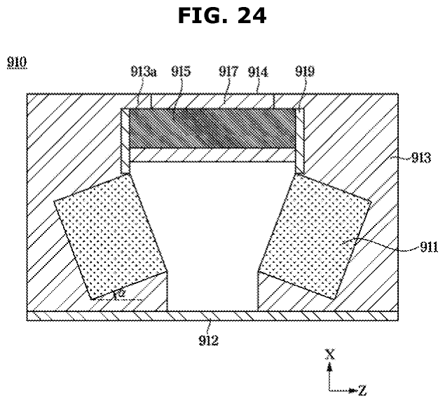

FIG. 24 shows a cross section of a light source module according to another embodiment of the disclosure.

Referring to FIG. 24, a light source module 910 according to another embodiment of the disclosure will be described. The light source module 910 shown in FIG. 24 may be applied to the display apparatus 1 shown in FIGS. 3 to 5.

Referring to FIG. 24, the light source module 910 may be provided to emit light. The light source module 910 may include a light source 911, a light source cover 913, a light conversion member 915, and a conversion member cover 917.

A blue light emitting diode (LED) may be used as the light source 911. In addition, a cold cathode fluorescent lamp (CCFL) and an external electrode fluorescent lamp (EEFL) may also be used.

The light source 911 may be provided as a plurality of light sources 911 to be symmetrical with respect to approximately the center of the light source module 910. The light source 911 may be provided to emit light from all surfaces other than one surface thereof.

The light source cover 913 may be provided to cover the light source 911.

The light source module 910 may include a substrate reflection layer 912 disposed between the substrate 101 and the light source cover 913. The substrate reflection layer 912 may be configured to reflect light. The substrate reflection layer 912 may be attached to the substrate 101 of the embodiment shown in FIGS. 3 to 5. The substrate reflection layer 912 may be provided to electrically connect the light source 911 and the substrate 101.

The light source 911 may be obliquely disposed with respect to a direction in which the substrate reflection layer 912 extends. The light source 911 may be disposed such that one side that emits light is inclined toward the light conversion member 915. With such a configuration, light emitted from the light source module 910 may be condensed.

The light source cover 913 may be provided to condense the light emitted from the light source 911 toward the light conversion member 915. That is, the light source cover 913 may be provided to block light emitted from surfaces of the light source 911 other than a surface facing the light conversion member 915. To the end, the light source cover 913 may be provided to cover the surfaces other than the surface of the light source 911 facing the light conversion member 915. The light source cover 913 may be formed of a material through which light may not pass. The light source cover 913 may be provided to electrically connect the substrate 901 and the light source 911. The light source cover 913 may be in contact with a surface of the light source 911 to support the light source 911.

The light source cover 913 may include a light guide 913a formed to cover a portion of a light exit surface of the light conversion member 915. Specifically, the light guide 913a may be provided to cover an outer portion of the light exit surface of the light conversion member 915. Accordingly, the light guide 913a may condense the light emitted through the light conversion member 915.

A light exit portion 914 may be formed between the light guides 913a Light passed through the light conversion member 915 may be emitted through the light exit portion 914.

The light conversion member 915 may be provided to improve color gamut. The light conversion member 915 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material. The luminescent material forming the phosphor is not limited thereto.

The conversion member cover 917 may be disposed on the other side of the light source 911 opposite to one side on which the substrate reflection layer 912 is disposed. The conversion member cover 917 may be provided to cover at least a portion of the light conversion member 915. The conversion member cover 917 may be provided to cover a portion of a light incident surface and a light exit surface of the light conversion member 915. A portion of the conversion member cover 917 may be disposed between the light guides 913a.

The conversion member cover 917 may prevent the light conversion member 915 from being degraded or damaged by the light source 911, thereby preventing a decrease in functionality. The conversion member cover 917 may protect the light conversion member 915 from external foreign substances. The conversion member cover 917 may prevent the light conversion member 915 from being oxidized.

The conversion member cover 917 may be provided to allow light emitted from the light source 911 to pass therethrough. The conversion member cover 917 may be provided to allow light converted by the light conversion member 915 to pass therethrough.

At least a portion of the front surface of the conversion member cover 917 may be provided as a light exit portion 914. Light passed through the light conversion member 915 may be emitted through the light exit portion 914.

The light source module 910 may include a reflective member 919 provided to cover at least a portion of the light conversion member 915. The reflective member 919 may be provided to cover outer surfaces of the light conversion member 915, other than the light incident surface and the light exit surface. The reflective member 919 may be disposed between the light conversion member 915 and the light source cover 913. The reflective member 919 may prevent light from exiting through surfaces other than the light exit portion 914 of the light conversion member 915. As the reflective member 919 is provided to contact the outer surface of the light conversion member 915, loss of light may be prevented.

The reflective member 919 may be configured to reflect light. The reflective member 919 may guide Light passed through the light conversion member 915 to be emitted through the light exit portion 914. The reflective member 919 may guide light incident onto the conversion member cover 917 to pass through the light conversion member 915.

With such a configuration, the light source module 900 according to the embodiment of the disclosure may include the light conversion member 915 that is implemented to improve color gamut, so that a sheet for improving the color gamut is omitted, thereby simplifying the manufacturing process, reducing the unit cost of the product, and providing the display apparatus 1 with a reduced thickness.

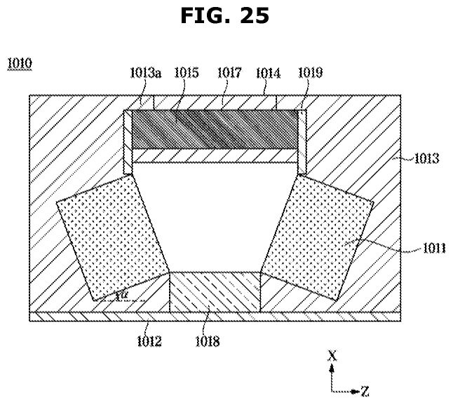

FIG. 25 shows a cross section of a light source module according to another embodiment of the disclosure.

Referring to FIG. 25, a light source module 1010 according to another embodiment of the disclosure will be described. The light source module 1010 shown in FIG. 25 may be applied to the display apparatus 1 shown in FIGS. 3 to 5.

Referring to FIG. 25, the light source module 1010 may be provided to emit light. The light source module 1010 may include a light source 1011, a light source cover 1013, a light conversion member 1015, and a conversion member cover 1017.

A blue light emitting diode (LED) may be used as the light source 1011. In addition, a cold cathode fluorescent lamp (CCFL) and an external electrode fluorescent lamp (EEFL) may also be used.

The light source 1011 may be provided as a plurality of light sources 1011 to be symmetrical with respect to approximately the center of the light source module 1010. The light source 1011 may be provided to emit light from all surfaces other than one surface thereof.

The light source cover 1013 may be provided to cover the light source 1011.

The light source module 1010 may include a substrate reflection layer 1012 disposed between the substrate 101 and the light source cover 1013. The substrate reflection layer 1012 may be configured to reflect light. The substrate reflection layer 1012 may be attached to the substrate 101 of the embodiment shown in FIGS. 3 to 5. The substrate reflection layer 1012 may be provided to electrically connect the light source 1011 and the substrate 101.

The light source 1011 may be obliquely disposed with respect to a direction in which the substrate reflection layer 1012 extends. The light source 1011 may be disposed such that one side that emits light is inclined toward the light conversion member 1015. With such a configuration, light emitted from the light source module 1010 may be condensed.

The light source cover 1013 may be provided to condense the light emitted from the light source 1011 toward the light conversion member 1015. That is, the light source cover 1013 may be provided to block light emitted from surfaces of the light source 1011 other than a surface facing the light conversion member 1015. To the end, the light source cover 1013 may be provided to cover the surfaces other than the surface of the light source 1011 facing the light conversion member 1015. The light source cover 1013 may be formed of a material through which light may not pass. The light source cover 1013 may be provided to electrically connect the substrate 1001 and the light source 1011. The light source cover 1013 may be in contact with a surface of the light source 1011 to support the light source 1011.

The light source cover 1013 may include a light guide 1013a formed to cover a portion of a light exit surface of the light conversion member 1015. Specifically, the light guide 1013a may be provided to cover an outer portion of the light exit surface of the light conversion member 1015. Accordingly, the light guide 1013a may condense the light emitted through the light conversion member 1015.

A light exit portion 1014 may be formed between the light guides 1013a. Light passed through the light conversion member 1015 may be emitted through the light exit portion 1014.

The light conversion member 1015 may be provided to improve color gamut. The light conversion member 1015 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material. The luminescent material forming the phosphor is not limited thereto.

The conversion member cover 1017 may be disposed on the other side of the light source 1011 opposite to one side on which the substrate reflection layer 1012 is disposed. The conversion member cover 1017 may be provided to cover at least a portion of the light conversion member 1015. The conversion member cover 1017 may be provided to cover a portion of a light incident surface and a light exit surface of the light conversion member 1015. A portion of the conversion member cover 1017 may be disposed between the light guides 1013a.

The conversion member cover 1017 may prevent the light conversion member 1015 from being degraded or damaged by the light source 1011, thereby preventing a decrease in functionality. The conversion member cover 1017 may protect the light conversion member 1015 from external foreign substances. The conversion member cover 1017 may prevent the light conversion member 1015 from being oxidized.

The conversion member cover 1017 may be provided to allow light emitted from the light source 1011 to pass therethrough. The conversion member cover 1017 may be provided to allow light converted by the light conversion member 1015 to pass therethrough.

At least a portion of the front surface of the conversion member cover 1017 may be provided as a light exit portion 1014. Light passed through the light conversion member 1015 may be emitted through the light exit portion 1014.

The light source module 1010 may include a reflective member 1019 provided to cover at least a portion of the light conversion member 1015. The reflective member 1019 may be provided to cover outer surfaces of the light conversion member 1015, other than the light incident surface and the light exit surface. The reflective member 1019 may be disposed between the light conversion member 1015 and the light source cover 1013. The reflective member 1019 may prevent light from exiting through surfaces other than the light exit portion 1014 of the light conversion member 1015.

The reflective member 1019 may be configured to reflect light. The reflective member 1019 may guide Light passed through the light conversion member 1015 to be emitted through the light exit portion 1014. The reflective member 1019 may guide light incident onto the conversion member cover 1017 to pass through the light conversion member 1015. As the reflective member 1019 is provided to contact the outer surface of the light conversion member 1015, loss of light may be prevented.

The light source module 1010 may include a reflective block 1018. The reflective block 1018 may be provided to reflect light emitted from the light source 1011. Part of the light emitted from the light source 1011 may be reflected from the reflective block 1018 to the light conversion member 1015. The reflective block 1018 may include a material with a higher reflectivity than the substrate reflection layer 1012.

With such a configuration, the light source module 1010 according to the embodiment of the disclosure may include the light conversion member 1015 that is implemented to improve color gamut, so that a sheet for improving the color gamut is omitted, thereby simplifying the manufacturing process, reducing the unit cost of the product, and providing the display apparatus 1 with a reduced thickness.

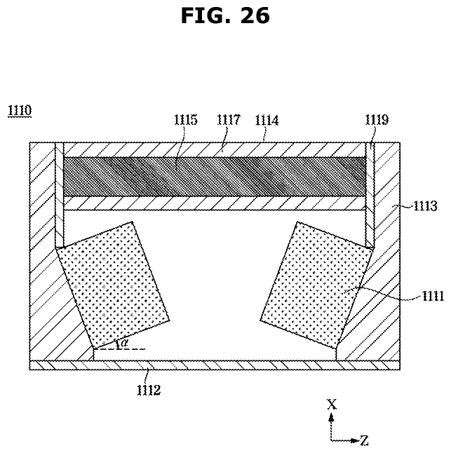

FIG. 26 shows a cross section of a light source module according to another embodiment of the disclosure.

Referring to FIG. 26, a light source module 1110 according to another embodiment of the disclosure will be described. The light source module 1110 shown in FIG. 26 may be applied to the display apparatus 1 shown in FIGS. 3 to 5.

Referring to FIG. 26, the light source module 1110 may be provided to emit light. The light source module 1110 may include a light source 1111, a light source cover 1113, a light conversion member 1115, and a conversion member cover 1117.

A blue light emitting diode (LED) may be used as the light source 1111. In addition, a cold cathode fluorescent lamp (CCFL) and an external electrode fluorescent lamp (EEFL) may also be used.

The light source 1111 may be provided as a plurality of light sources 1111 to be symmetrical with respect to approximately the center of the light source module 1110. The light source 1111 may be provided to emit light from all surfaces other than one surface thereof.

The light source cover 1113 may be provided to cover the light source 1111.

The light source module 1110 may include a substrate reflection layer 1112 disposed between the substrate 101 and the light source cover 1113. The substrate reflection layer 1112 may be configured to reflect light. The substrate reflection layer 1112 may be attached to the substrate 101 of the embodiment shown in FIGS. 3 to 5. The substrate reflection layer 1112 may be provided to electrically connect the light source 1111 and the substrate 101.

The light source 1111 may be obliquely disposed with respect to a direction in which the substrate reflection layer 1112 extends. The light source 1111 may be disposed such that one side that emits light is inclined toward the light conversion member 1115. With such a configuration, light emitted from the light source module 1110 may be condensed.

The light source cover 1113 may be provided to condense the light emitted from the light source 1111 toward the light conversion member 1115. The light source cover 1113 may be in contact with a surface of the light source 1111 to support the light source 1111. The light source cover 1113 may be provided to block light emitted from the light source 1111. The light source cover 1113 may be formed of a material through which light may not pass. The light source cover 1113 may be provided to electrically connect the substrate 1101 and the light source 1111.

The light conversion member 1115 may be provided to improve color gamut. The light conversion member 1115 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material. The luminescent material forming the phosphor is not limited thereto.

The conversion member cover 1117 may be disposed on the other side of the light source 1111 opposite to one side on which the substrate reflection layer 1112 is disposed. The conversion member cover 1117 may be provided to cover the light conversion member 1115. The conversion member cover 1117 may prevent the light conversion member 1115 from being degraded or damaged by the light source 1111, thereby preventing a decrease in functionality. The conversion member cover 1117 may protect the light conversion member 1115 from external foreign substances. The conversion member cover 1117 may prevent the light conversion member 1115 from being oxidized.

The conversion member cover 1117 may be provided to allow light emitted from the light source 1111 to pass therethrough. The conversion member cover 1117 may be provided to allow light converted by the light conversion member 1115 to pass therethrough.

At least a portion of the front surface of the conversion member cover 1117 may be provided as a light exit portion 1114. Light passed through the light conversion member 1115 may be emitted through the light exit portion 1114.

The light source module 1110 may include a reflective member 1119 provided to cover at least a portion of the conversion member cover 1117. The reflective member 1119 may be provided to cover outer surfaces of the conversion member cover 1117, other than the light incident surface and the light exit portion 1114. The reflective member 1119 may be disposed between the conversion member cover 1117 and the light source cover 1113.

The reflective member 1119 may be configured to reflect light. The reflective member 1119 may guide Light passed through the light conversion member 1115 to be emitted through the light exit portion 1114. The reflective member 1119 may guide light incident onto the conversion member cover 1117 to pass through the light conversion member 1115. The reflective member 1119 may prevent light that has not passed through the light conversion member 1115 from exiting the conversion member cover 1117. The reflective member 1119 may prevent light from exiting through other portions than the light exit portion 1114 of the conversion member cover 1117.

With such a configuration, the light source module 1110 according to the embodiment of the disclosure may include the light conversion member 1115 that is implemented to improve color gamut, so that a sheet for improving the color gamut is omitted, thereby simplifying the manufacturing process, reducing the unit cost of the product, and providing the display apparatus 1 with a reduced thickness.

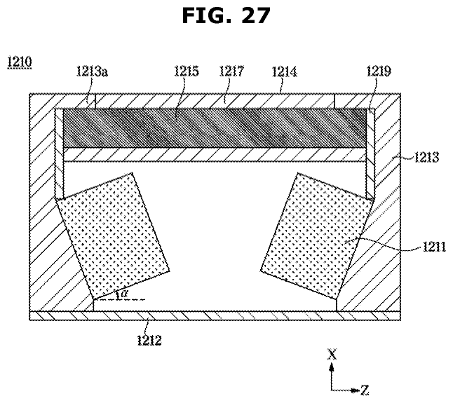

FIG. 27 shows a cross section of a light source module according to another embodiment of the disclosure.

Referring to FIG. 27, a light source module 1210 according to another embodiment of the disclosure will be described. The light source module 1210 shown in FIG. 27 may be applied to the display apparatus 1 shown in FIGS. 3 to 5.

Referring to FIG. 27, the light source module 1210 may be provided to emit light. The light source module 1210 may include a light source 1211, a light source cover 1213, a light conversion member 1215, and a conversion member cover 1217.

A blue light emitting diode (LED) may be used as the light source 1211. In addition, a cold cathode fluorescent lamp (CCFL) and an external electrode fluorescent lamp (EEFL) may also be used.

The light source 1211 may be provided as a plurality of light sources 1211 to be symmetrical with respect to approximately the center of the light source module 1210. The light source 1211 may be provided to emit light from all surfaces except one surface thereof.

The light source cover 1213 may be provided to cover the light source 1211.

The light source module 1210 may include a substrate reflection layer 1212 disposed between the substrate 101 and the light source cover 1213. The substrate reflection layer 1212 may be configured to reflect light. The substrate reflection layer 1212 may be attached to the substrate 101 of the embodiment shown in FIGS. 3 to 5. The substrate reflection layer 1212 may be provided to electrically connect the light source 1211 and the substrate 101.

The light source 1211 may be obliquely disposed with respect to a direction in which the substrate reflection layer 1212 extends. The light source 1211 may be disposed such that one side that emits light is inclined toward the light conversion member 1215. With such a configuration, light emitted from the light source module 1210 may be condensed.

The light source cover 1213 may be provided to condense the light emitted from the light source 1211 toward the light conversion member 1215. The light source cover 1213 may be in contact with a surface of the light source 1211 to support the light source 1211. The light source cover 1213 may be provided to block light emitted from the light source 1211. The light source cover 1213 may be formed of a material through which light may not pass. The light source cover 1213 may be provided to electrically connect the substrate 1101 and the light source 1211.

The light source cover 1213 may include a light guide 1213a formed to cover a portion of a light exit surface of the light conversion member 1215. Specifically, the light guide 1213a may be provided to cover an outer portion of the light exit surface of the light conversion member 1215. Accordingly, the light guide 1213a may condense the light emitted through the light conversion member 1215.

A light exit portion 1214 may be formed between the light guides 1213a. Light passing through the light conversion member 1215 may be emitted through the light exit portion 1214.

The light conversion member 1215 may be provided to improve color gamut. The light conversion member 1215 may include a phosphor that converts the wavelength of incident light and emits the converted light. For example, the phosphor includes at least one luminescent material selected from a Yttrium aluminum garnet (YAG) based luminescent material, a terbium aluminum garnet (TAG) based luminescent material, a silicate based luminescent material, a sulfide based luminescent material, a nitride based luminescent material, a borate based luminescent material, and a phosphate based luminescent material.

The luminescent material forming the phosphor is not limited thereto.

The conversion member cover 1217 may be disposed on the other side of the light source 1211 opposite to one side on which the substrate reflection layer 1212 is disposed. The conversion member cover 1217 may be provided to cover the light conversion member 1215. The conversion member cover 1217 may prevent the light conversion member 1215 from being degraded or damaged by the light source 1211, thereby preventing a decrease in functionality. The conversion member cover 1217 may protect the light conversion member 1215 from external foreign substances. The conversion member cover 1217 may prevent the light conversion member 1215 from being oxidized.

The conversion member cover 1217 may be provided to allow light emitted from the light source 1211 to pass therethrough. The conversion member cover 1217 may be provided to allow light converted by the light conversion member 1215 to pass therethrough.

At least a portion of the front surface of the conversion member cover 1217 may be provided as a light exit portion 1214. Light passed through the light conversion member 1215 may be emitted through the light exit portion 1214.

The light source module 1210 may include a reflective member 1219 provided to cover at least a portion of the conversion member cover 1217. The reflective member 1219 may be provided to cover outer surfaces of the conversion member cover 1117, other than the light incident surface and the light exit portion 1214. The reflective member 1219 may be disposed between the conversion member cover 1217 and the light source cover 1213.

The reflective member 1219 may be configured to reflect light. The reflective member 1219 may guide Light passed through the light conversion member 1215 to be emitted through the light exit portion 1214. The reflective member 1219 may guide light incident onto the conversion member cover 1217 to pass through the light conversion member 1215. The reflective member 1219 may prevent light that has not passed through the light conversion member 1215 from exiting the conversion member cover 1217. The reflective member 1219 may prevent light from exiting through other portion than the light exit portion 1214 of the conversion member cover 1217.

With such a configuration, the light source module 1210 according to the embodiment of the disclosure may include the light conversion member 1215 that is implemented to improve color gamut, so that a sheet for improving the color gamut is omitted, thereby simplifying the manufacturing process, reducing the unit cost of the product, and providing the display apparatus 1 with a reduced thickness.

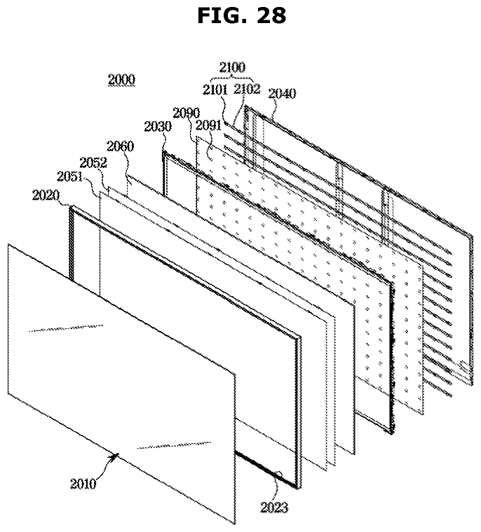

FIG. 28 is an exploded view showing main parts of a display apparatus according to another embodiment of the disclosure.

The technical concept of the disclosure may be applied not only to the light guide plate of the above-described edge-type backlight unit but also to a diffuser plate of a direct-type backlight unit. Hereinafter, description of the same configuration as those in the above-described embodiments may be omitted.

Referring to FIG. 28, a display apparatus 2 includes a display panel 2010 that displays an image, a backlight unit disposed at the rear of the display panel 2010 to provide light to the display panel 2010, and a chassis assembly for supporting the backlight unit and the display panel 2010.

The chassis assembly includes a rear chassis 2040 provided to support the backlight unit, a front chassis 2020 provided at the front of the rear chassis 2040 to support the display panel 2010, and a middle mold 2030 coupled between the front chassis 2020 and the rear chassis 2040.

The backlight unit may be disposed at the rear of the display panel 2010 and emit light toward the display panel 2010. The backlight unit may include a light source device 2100 including a light source 2101 and a substrate 2102 on which the light source 2101 is mounted, and optical members disposed on a travel path of light emitted from the light source 2101. The light source device 2100 may be provided in the same manner as the light source device 100 shown in FIG. 2.

The optical members may be disposed on the path of light emitted from the light source 2101 to guide the direction of light, reflect light, diffuse light, or improve optical characteristics.

The optical members may include a reflector sheet 2090 that reflects light to prevent light loss, a diffuser plate 2060 that uniformly diffuses non-uniform light emitted from the light source 2101, and optical sheets 2051 and 2052 that improve optical characteristics.

The reflector sheet 2090 may reflect light emitted from the light source 2101 or light exiting backward from the diffuser plate 2060 to the diffuser plate 2060. The reflector sheet 2090 may be disposed on the substrate 2102. The reflector sheet 2090 may be in close contact with the substrate 2102. A through hole 2091 may be formed in the reflector sheet 2090 to allow the light source 2101 to pass therethrough.

The diffuser plate 2060 may uniformly diffuse non-uniform light generated from the plurality of light sources 2101 and support the optical sheets 2051 and 2052. The diffuser plate 2060 may uniformly diffuse light introduced through an incident surface and emit the light through an exit surface.

The rear chassis 2040 is disposed at the rear of the backlight unit. The rear chassis 2040 may have a substantially plate shape with an edge portion bent forward. The backlight unit may be accommodated between the rear chassis 2040 and the front chassis 2020.

The rear chassis 2040 may include a rear base portion on which the light source device 2100 is installed, and rear side portions formed at the upper, lower, left, and right edges of the rear chassis 2040 to be coupled to the middle mold 2030.

The front chassis 2020 may have a frame shape with an opening 2023 through which light from the backlight unit is provided to the display panel 2010. The front chassis 2020 includes front side portions formed on the upper, lower, left, and right edges of the front chassis 2020 to be coupled to the middle mold 2030, and a panel support portion protruding inward from the front side portion to support the display panel 2010.

The middle mold 2030 may support the diffuser plate 2060 and allow the diffuser plate 2060 and the light source device 2100 to be kept spaced apart from each other. The middle mold 2030 may be coupled between the front chassis 2020 and the rear chassis 2040.

The diffuser plate 2060 may be formed in an approximately hexahedral shape including an incident surface and an exit surface.

According to one or more embodiments of the disclosure, the display apparatus is provided with components for improving color gamut in a light source device, so that a separate optical sheet for improving color gamut can be omitted, thereby simplifying the manufacturing process.

According to one or more embodiments of the disclosure, the display apparatus is provided with components for improving color gamut in a light source device, so that a separate optical sheet for improving color gamut can be omitted, thereby reducing the manufacturing cost.

According to one or more embodiments of the disclosure, the display apparatus is provided with components for improving color gamut in a light source device, so that a separate optical sheet for improving color gamut can be omitted, thereby achieving a reduced thickness.

Although embodiments of the disclosure have been shown and described, the above embodiment is illustrative purpose only, and it would be appreciated by those skilled in the art that changes and modifications may be made in these embodiments without departing from the principles and scope of the disclosure, the scope of which is defined in the claims and their equivalents.

What is claimed is:

1. A display apparatus comprising:
a light source device configured to emit light;
a display panel configured to display the light emitted from the light source device; and
an optical sheet disposed at a rear of the display panel,
wherein the light source device comprises:
a substrate;
at least one light source electrically connected to the substrate;
a light conversion member configured to convert a wavelength of light emitted from the light source; and
a conversion member cover covering the light conversion member and configured to allow light to pass therethrough.

2. The display apparatus of claim 1, wherein the at least one light source comprises a first light source on a first side of the light conversion member and a second light source on a second side of the light conversion member opposite to the first side.

3. The display apparatus of claim 1, wherein the conversion member cover is disposed on the substrate.

4. The display apparatus of claim 1, wherein the light source contacts the conversion member cover.

5. The display apparatus of claim 1, wherein the light source device further comprises a light source cover covering the light source and configured to block light emitted from the light source.

6. The display apparatus of claim 5, wherein the light source cover comprises a light guide configured to cover a surface of the conversion member cover from which light is emitted, except for an area corresponding to the light conversion member.

7. The display apparatus of claim 5, wherein the light conversion member is disposed on a first side of the light source opposite to a second side of the light source on which the substrate is located.

8. The display apparatus of claim 7, wherein the light source device further comprises a reflective member covering at least a portion of the conversion member cover and configured to reflect light.

9. The display apparatus of claim 7, wherein the light source is inclined with respect to the substrate.

10. The display apparatus of claim 9, wherein the light source device further comprises a conversion member reflection layer between the conversion member cover and the light source cover and configured to reflect light.

11. The display apparatus of claim 9, wherein the light source device further comprises a conversion member reflection layer between the light conversion member and the light source cover and configured to reflect light.

12. The display apparatus of claim 9, wherein the light source device further comprises a substrate reflection layer between the substrate and the light source cover and configured to reflect light.

13. The display apparatus of claim 12, wherein the light source device further comprises a reflective block on the substrate reflection layer and configured to reflect light emitted from the light source.

14. The display apparatus of claim 9, wherein the light source cover covers only a first surface of the light source.

15. The display apparatus of claim 9, wherein the light source cover covers at least two surfaces of the light source.
